(19) United States
(12) Patent Application Publication
(10) Pub. No.: US 2024/0098921 A1
(43) Pub. Date: Mar. 21, 2024

(54) ELECTRONIC DEVICE INCLUDING A STRUCTURALLY COLORED ENCLOSURE COMPONENT

(71) Applicant: Apple Inc., Cupertino, CA (US)

(72) Inventors: Que Anh S. Nguyen, San Jose, CA (US); Weidi Zhu, Milpitas, CA (US); Nisha S. Sheth, San Mateo, CA (US); Andi M. Limarga, Cupertino, CA (US)

(21) Appl. No.: 18/239,686

(22) Filed: Aug. 29, 2023

Related U.S. Application Data
(60) Provisional application No. 63/408,527, filed on Sep. 21, 2022.

(51) Int. Cl. H05K 5/03; H04M 1/02

(52) U.S. Cl. CPC H05K 5/03; H04M 1/0264; H04M 1/0266

(57) ABSTRACT

A structurally colored enclosure component for an electronic device is disclosed. The structurally colored enclosure component may be a cover member for the electronic device and in some cases may display iridescence. A surface region of the enclosure component may include a modified glass-based material and the structural color of the enclosure component may be due at least in part to the surface region. Enclosures and electronic devices including the structurally colored enclosure components are also described herein,

### CROSS-REFERENCE TO RELATED APPLICATION(S)

This application is a nonprovisional application of and claims the benefit of U.S. Provisional Patent Application 63/408,527, filed Sep. 21, 2022, and titled “Electronic Device Including a Structurally Colored Enclosure Component,” the disclosure of which is hereby incorporated herein by reference in its entirety.

### FIELD

The described embodiments relate generally to structurally colored enclosure components for electronic devices. More particularly, the present embodiments relate to structurally colored enclosure components that are formed from a glass-based material.

### BACKGROUND

Enclosures for portable electronic devices may be colored in several ways. In some cases, a coating including a coloring agent may be applied to one or more of the enclosure components. In additional cases, a coloring agent may be included in the material used to form the enclosure component. Embodiments described herein are directed to structurally colored enclosure components that may have advantages as compared to some traditionally colored enclosure components.

### SUMMARY

Embodiments described herein relate generally to structurally colored enclosure components for electronic devices. The structurally colored enclosure components described herein are typically formed from a glass-based material and in some cases may be a cover member for the electronic device. Enclosures and electronic devices including these structurally colored enclosure components are also described herein.

In some embodiments, a surface region of the enclosure component includes a modified glass-based material, and the structural color of the enclosure component is due at least in part to the surface region. In some cases, the enclosure component may be configured to produce an iridescent effect, so that the color of the surface region changes with the angle of light incidence and/or the angle of observation. In additional cases, the enclosure component may be configured to produce a lustrous effect similar to that produced by a pearl. Enclosure components that produce both luster and iridescence are also within the scope of this disclosure.

In some embodiments, the enclosure component is formed at least in part by modifying a surface zone of a workpiece formed from a glass-based material. The modified glass-based material of the surface zone typically has a structure that differs from that of the unmodified glass-based material. For example, the modified glass-based material may include structural features such pores, crystals, a phase separated structure, or the like that are not present in the unmodified glass-based material or that are present in the unmodified glass-based material in a different form and/or amount. In some examples, the modified glass-based material has a lower effective index of refraction than the unmodified glass-based material.

Enclosure components, such as cover members, having a structural color can have several advantages as compared to conventional enclosure components. For example, the color of the enclosure components described herein can be more durable than some conventional coatings applied to the exterior of an enclosure component. As an additional example, the color of the enclosure components described herein can be produced without undesirably increasing the dielectric constant of the enclosure component. As a further example, the color of the enclosure components described herein can have additional effects such as iridescence that may be difficult to achieve solely with a coloring agent included in the enclosure component.

In some embodiments, the surface region and the underlying substrate act together to produce an optical effect. In some cases, the surface region of the enclosure component defines a thin film that can produce an optical effect through interference of light reflected from the surface of the surface region and light reflected from interface between the surface region and the underlying substrate. The surface region of the enclosure may have a lower effective refractive index than an underlying substrate. Therefore, the surface region and the substrate may be configured to produce a reflected color that varies as a function of viewing angle and/or illumination angle, also referred to herein as an iridescent effect. In some cases, the size and/or spacing of structural features within the surface region are much smaller than wavelengths of visible light within the surface region, so that the internal structure of the surface region defines an effective medium for light traveling through the surface region. For example, the surface region may include pores sized configured to produce an effective index of refraction in the surface region that is less than that of the underlying substrate. The thickness of the surface region may be less than one micrometer in some examples.

In additional embodiments, interaction of light with structural features within the surface region contributes to the optical effect. In some cases, the interaction of light with structural features within the surface region may be the dominant effect producing the structural color of the enclosure component. In such cases, the size and/or spacing of the structural features within the surface region may be generally on the order of one or more wavelengths of visible light within the surface region. For example, an internal structure of the surface region configured to produce an iridescent effect may define interfaces between different phases having different refractive indices. Light traveling through the surface region may interact with several of these interfaces to produce the iridescent effect through a mechanism such as interference or diffraction. As an additional example, the internal structure may define regularly repeating regions of higher and lower refractive index that define a photonic crystal.

The disclosure provides a portable electronic device comprising a display and an enclosure including a cover assembly comprising a unitary cover member. The unitary cover member comprises a substrate region formed from a first glass-based material and having a first refractive index and a surface region adjacent to the substrate region and defining an exterior surface of the unitary cover member, the surface region comprising a matrix formed from a second glass-based material and having a second refractive index and an array of features within the matrix and having a third refractive index that is different than the first refractive index, the substrate region and the surface region configured to produce a reflected color that varies as a function of viewing angle.

The disclosure also provides an electronic device comprising an enclosure comprising a housing assembly and a rear cover assembly coupled to the housing assembly, defining a rear surface of the electronic device, and including a cover member and a polymer-based coating disposed over an interior surface of the cover member, the polymer-based coating configured to reflect at least a portion of light transmitted through the cover member, and an internal electronic component positioned within the enclosure. The cover member comprises a first layer defined by a first glass-based material having a first index of refraction and a second layer defining an exterior surface of the cover member, defined by a second glass-based material, and having a second index of refraction that is less than the first index of refraction, the surface and the substrate layers configured to produce an iridescent optical effect along the exterior surface of the electronic device. The internal electronic component is positioned below the first layer and the second layer of the cover member.

The disclosure also provides a portable electronic device comprising a display, a camera assembly, and an enclosure at least partially surrounding the display. The enclosure comprises a housing assembly defining a set of side surfaces of the portable electronic device, a front cover assembly positioned over the display and defining a front surface of the portable electronic device, and a rear cover assembly positioned over the camera assembly and defining a rear surface of the portable electronic device. The rear cover assembly includes a cover member defining a substrate region defining an interior surface of the cover member, comprising a first glass-based material, and having a first internal structure, and a surface region defining an exterior surface of the cover member, comprising a second glass-based material, and having a second internal structure different from the first internal structure and configured to produce iridescence at the exterior surface of the cover member.

### BRIEF DESCRIPTION OF THE DRAWINGS

The disclosure will be readily understood by the following detailed description in conjunction with the accompanying drawings, wherein like reference numerals designate like elements.

FIGS. 1A and 1B show views of an example electronic device.

FIG. 2 shows a partial cross-section view of an electronic device.

FIG. 3 shows another partial cross-section view of an electronic device.

FIG. 4 shows an example enclosure component.

FIG. 5 shows a partial cross-section view of an enclosure component.

FIG. 6 shows another partial cross-section view of an enclosure component.

FIG. 7 shows another partial cross-section view of an enclosure component.

FIG. 8 shows another partial cross-section view of an enclosure component.

FIG. 9 shows another partial cross-section view of an enclosure component.

FIG. 10 shows another partial cross-section view of an enclosure component.

FIG. 11 shows another partial cross-section view of an enclosure component.

FIG. 12 shows another partial cross-section view of an enclosure component.

FIG. 13 shows another enclosure component.

FIG. 14 shows a partial cross-section view of an enclosure component.

FIG. 15 shows an example of another electronic device.

FIG. 16 shows a block diagram of an example electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred implementation. To the contrary, the described embodiments are intended to cover alternatives, modifications, and equivalents as can be included within the spirit and scope of the disclosure and as defined by the appended claims.

Embodiments described herein relate generally to structurally colored enclosure components for electronic devices. The structurally colored enclosure components described herein are typically formed from a glass-based material and in some cases may be a cover member for the electronic device. Enclosures and electronic devices including these structurally colored enclosure components are also described herein.

In some embodiments, the enclosure component is formed least in part by modifying a surface zone of a workpiece that is formed from a glass-based material. The modified glass-based material of the surface zone typically has a structure that differs from that of the unmodified glass-based material. For example, the modified glass-based material may include structural features such pores, particles (e.g., crystals), a phase separated structure, or the like that are not present in the unmodified glass-based material or that are present in the unmodified glass-based material in a different form and/or amount. In some cases, the structural features define an array, such as an array of pores or an array of crystals. In some examples, the modified glass-based material has a lower effective index of refraction than the unmodified glass-based material.

In some embodiments, a surface region of the enclosure component includes the modified glass-based material, and the structural color of the enclosure component is due at least in part to the surface region. In some cases, the enclosure component may be configured to produce an iridescent effect, so that the color of the surface region changes with the angle of light incidence and/or observation. In additional cases, the enclosure component may be configured to produce a lustrous effect similar to that produced by a pearl. Enclosure components that produce both luster and iridescence are also within the scope of this disclosure.

Enclosure components, such as cover members, having a structural color can have several advantages as compared to conventional enclosure components. For example, the color of the enclosure components described herein can be more durable than some conventional coatings applied to the exterior of an enclosure component. As an additional example, the color of the enclosure components described herein can be produced without undesirably increasing the dielectric constant of the enclosure component. As a further example, the color of the enclosure components described herein can have additional effects such as iridescence that may be difficult to achieve solely with a coloring agent included in the enclosure component.

In some embodiments, the surface region and the underlying substrate act together to produce an optical effect. In some cases, the surface region of the enclosure component defines a thin film that can produce an optical effect through interference of light reflected from the surface of the surface region and light reflected from interface between the surface region and the underlying substrate. The surface region of the enclosure may have a lower effective refractive index than an underlying substrate. Therefore, the surface region and the substrate may be configured to produce a reflected color that varies as a function of viewing angle and/or illumination angle, also referred to herein as an iridescent effect. In some cases, the size and/or spacing of structural features within the surface region are much smaller than wavelengths of visible light within the surface region, so that the internal structure of the surface region defines an effective medium for light traveling through the surface region. For example, the surface region may include pores sized configured to produce an effective index of refraction in the surface region that is less than that of the underlying substrate. The thickness of the surface region may be less than one micrometer in some examples. Embodiments in which the surface region of the enclosure component defines thin layers of alternating high and low refractive index are also within the scope of this disclosure.

In additional embodiments, interaction of light with structural features within the surface region contributes to the optical effect. In some cases, the interaction of light with structural features within the surface region may be the dominant effect producing the structural color of the enclosure component. In such cases, the size and/or spacing of the structural features within the surface region may be generally on the order of one or more wavelengths of visible light within the surface region. For example, an internal structure of the surface region configured to produce an iridescent effect may define interfaces between different phases having different refractive indices. Light traveling through the surface region may interact with several of these interfaces to produce the iridescent effect through a mechanism such as interference or diffraction. As an additional example, the internal structure may define regularly repeating regions of higher and lower refractive index that define a photonic crystal.

In some embodiments, the structurally colored enclosure component also includes a coloring agent. The coloring agent may be present in the surface region, the substrate region, or both. In these embodiments, the color of the enclosure component may be due to the combined effects of the structural color and the color agent.

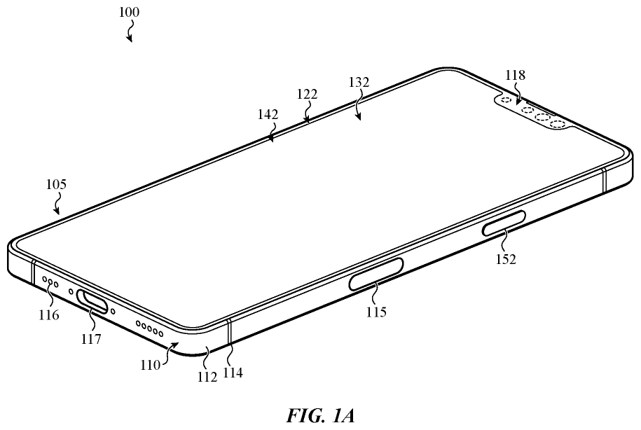

These and other embodiments are discussed below with reference to FIGS. 1A-16. However, those skilled in the art will readily appreciate that the detailed description given herein with respect to these figures is for explanatory purposes only and should not be construed as limiting.

FIGS. 1A and 1B show an example of an electronic device or simply “device” 100. For purposes of this disclosure, the device 100 may be a portable electronic device including, for example a mobile phone, a tablet computer, a portable computer, a laptop, a wearable electronic device, a portable music player, a health monitoring device, a portable terminal, a wireless charging device, a device accessory, or other portable or mobile device.

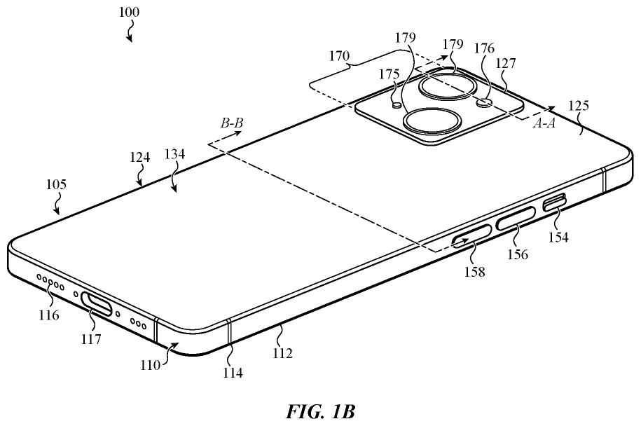

As shown in FIGS. 1A and 1B, the electronic device 100 includes an enclosure 105. The enclosure 105 includes a front cover assembly 122, a rear cover assembly 124, and an enclosure component 110. Internal components of the device may be at least partially enclosed by the front and rear cover assemblies 122, 124 and the enclosure component 110 and, in some cases, may be positioned within an internal cavity defined by the enclosure (e.g., 201 of FIG. 2). The example of FIGS. 1A and 1B is not limiting and in other examples internal components of the device may be enclosed by an enclosure component in combination with a unitary cover or any other suitable configuration. A unitary cover may be formed from a single piece of material and may alternately be referred to as a monolithic cover.

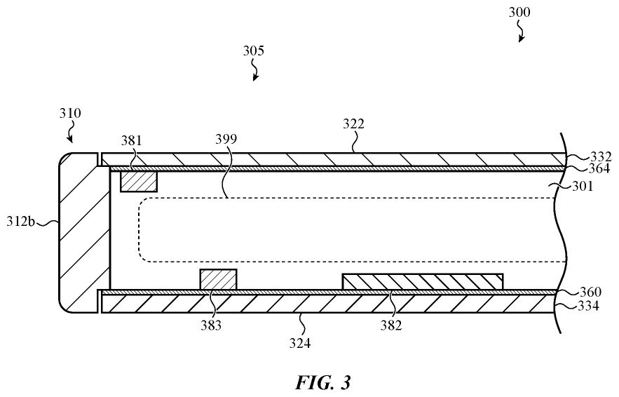

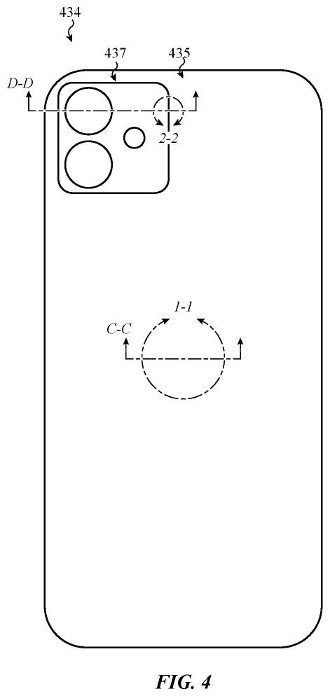

The enclosure 105 includes a structurally colored enclosure component. In the example of FIGS. 1A and 1B, the rear cover assembly 124 may include a structurally colored enclosure component. In some embodiments, the structural color of the enclosure component is due at least in part to a surface region of the enclosure component which has a structure that differs from that of an underlying (e.g., unmodified) region of the enclosure component. This underlying region may also be referred to herein as a substrate region of the enclosure component. In some cases, the surface region of the enclosure component defines a thin film that can produce an optical effect through interference of light reflected from the surface of the surface region and light reflected from interface between the surface region and the underlying substrate. In additional cases, interaction of light with structural features within the surface region contributes to the optical effect. Additional description of structurally colored enclosure components is provided with respect to FIGS. 4 and 5, and, for brevity, that description is not repeated here.

In some examples, the structural color may be imparted along an entire surface of the enclosure component, such as an outward-facing surface of the enclosure component. In other examples, the structural color may be imparted to only a portion of the surface of the enclosure component. In some embodiments, the structurally colored enclosure component also includes a coloring agent present in the surface region, the substrate region, or both. In these embodiments, the color of the enclosure component may be due to the combined effects of the structural color and the color agent.

The front cover assembly 122 may at least partially define a front surface of the electronic device. In the example of FIG. 1A, the front cover assembly defines a substantial entirety of the front surface of the electronic device. In the example of FIG. 1A, the front cover assembly 122 includes a cover member 132 (also referred to herein as a front cover member). The cover member 132 may extend laterally across the cover assembly 122, such as substantially across the width and the length of the cover assembly. The front cover assembly 122 may also include an exterior coating such as an oleophobic coating and/or an anti-reflective coating. The front cover assembly 122 may also define an opening, which may be positioned over a speaker or another internal device. Alternately or additionally the front cover assembly 122 may include an interior coating such as a masking layer which provides an opaque portion of the front cover assembly 122. These exterior and/or interior coatings may be disposed on the cover member 132. In addition, the front cover assembly may include a mounting frame which is coupled to an interior surface of the cover member 132 and to the enclosure component 110.

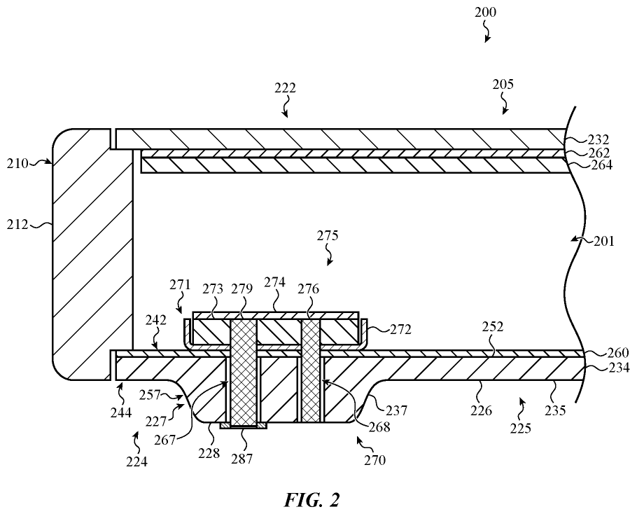

The front cover assembly 122 may be positioned over one or more electronic components of the electronic device. For example, the front cover assembly 122 is positioned over a display 142 and also shown in the cross-section view of FIG. 3. The front cover assembly 122 of FIG. 1A is also positioned over a front sensing array 118, with the components of the front sensing array shown with dashed lines.

In embodiments, the front cover assembly 122 is substantially transparent or includes one or more substantially transparent portions over the display 142 and/or an optical component configured to operate over a visible wavelength range (e.g., an optical component of the front sensing array 118). As referred to herein, a component or material is substantially transparent when light is transmitted through the material and the extent of scattering is low. The front cover assembly 122 may also be configured to have electrical properties and/or magnetic properties compatible with one or more internal components of the electronic device.

Typically, the cover member 132 is substantially transparent or includes one or more substantially transparent portions over a display and/or an optical component configured to operate over a visible wavelength range. The cover member 132 may also include one or more translucent and/or opaque portions in combination with the one or more substantially transparent portions. For example, the transmission of the cover member 132 (or the transparent portions thereof) may be at least 85%, 90%, or 95% over a visible wavelength range (e.g., the visible spectrum), and the haze may be less than about 5% or 1%. This transmission value may be an average value.

In addition, the cover member 132 or portions of the cover member 132 positioned over a display or optical module may be configured to have a sufficiently neutral color that the optical input to the optical module and/or the optical output provided by the display 142 is not significantly degraded. For example, these portions of the front cover member may be described by an L* value of 90 or more, an a* value having a magnitude (alternately, absolute value) less than 0.5, and a b* value having a magnitude less than 1.

The cover member 132 may also be configured to have additional optical properties, electrical properties, and/or magnetic properties compatible with one or more internal components of the electronic device. For example, the cover member 132 may be configured to provide infrared (IR) transmission suitable for use over an optical component configured to produce images from infrared light (e.g., near-IR light). In some cases, the cover member 132 may have a transmission value of at least 85%, 90%, or 95% over an infrared wavelength range (e.g., from 770 nm to 1000 nm). These transmission values may be average values over the infrared wavelength range. As an additional example, the cover member 132 may be configured to provide electrical properties suitable for use over a component of a wireless communication system. For example, the cover member 132 may be a dielectric cover member and may be formed from a material having a dielectric constant and a dissipation factor sufficiently low to allow transmission of RF or IR (e.g., near-IR) signals through the cover member. In some examples, the cover member 132 may define an opening over one or more internal components of the electronic device, such as an optical module of a camera assembly or a sensor assembly.

In some embodiments, the cover member 132 may be a structurally colored cover member as described herein. The structural color may be present only along some portions of the exterior surface and not present over portions of the cover member positioned over the display or another optical component. The structurally colored cover member may be formed from a glass-based material such as a glass or a glass ceramic material. In other cases, a cover member 132 other than a structurally colored cover member may be formed from a glass material, a glass ceramic material, a polymer material, a ceramic material, or a combination thereof. In some embodiments, the cover member 132 has a thickness less than 3 mm, less than or equal to 2 mm, less than or equal to 1 mm, from about 250 microns to about 1 mm, or from about 500 microns to about 1 mm.

The rear cover assembly 124 may at least partially define a rear surface of the electronic device. In the example of FIG. 1B, the rear cover assembly 124 defines a substantial entirety of the rear surface of the electronic device. The rear cover assembly 124 includes a cover member 134. The exterior surface of the rear cover member 134 may have a texture that produces a glossy effect, a matte effect, or combination of these. The rear cover assembly 124 may also include one or more coatings. For example, the rear cover assembly 124 may include an exterior coating such as a smudge-resistant (e.g., oleophobic) coating. Alternately or additionally, the rear cover assembly 124 may include one or more interior coatings which provide a decorative effect, such as a color layer, a multilayer interference stack, or a metal layer. Additional description of interior coatings is provided with respect to FIG. 2. These exterior and/or interior coatings may be disposed on the cover member 134. In addition, the rear cover assembly 124 may include a mounting frame which is coupled to an interior surface of the cover member 134 and to the enclosure component 110. In some cases, the rear cover assembly 124 is positioned over an electronic component, such as a wireless charging component or a wireless communication component, as illustrated in the cross-section view of FIG. 3. In some examples, the cover member 134 may define an opening over one or more internal components of the electronic device, such as an optical module of a rear-facing camera assembly or a sensor assembly. In these examples, the rear cover assembly 124 may also include at least one (optically) transparent window member positioned over the opening(s).

In the example of FIG. 1B, the rear cover assembly 124 defines a thinner portion 125 and a thicker portion 127. As shown in FIG. 1B, the thicker portion 127 of the cover assembly 124 protrudes or is offset with respect to a thinner portion 125 of the cover assembly 124. The thicker portion 127 of FIG. 1B has a raised surface that defines a plateau, as described in more detail with respect to the raised surface 228 of FIG. 2. The description provided with respect to these features in FIG. 2 is generally applicable herein. In some examples, the thicker portion 127 is integrally formed with the thinner portion. In additional examples, the thinner portion 125 may be provided by the cover member 134 while the thicker portion 127 may be provided at least in part by an additional cover member which is coupled to the thinner portion.

The thicker portion 127 of the cover assembly 124 may accommodate one or more components of a sensing array 170. In the example of FIG. 1B, the sensing array 170 includes multiple optical components 179 and 176. In some cases, the optical components are part of multiple camera assemblies. Each of the camera assemblies may include an optical component such as the optical components 179 and 176. Each of the optical components 179 and 176 may be positioned at least partially within a respective opening in the thicker portion 127, as shown for the optical components 279 and 276 in FIG. 2. The optical component 179 may be a camera module while the optical component 176 may be an illumination module. The sensing array 170 may also include one or more additional components, such as the component 175. In some cases, the component 175 is part of a sensor assembly. The sensor assembly may measure a distance to a target, such as a Lidar sensor assembly which is configured to illuminate an object with light and then detect the reflected light to determine or estimate the distance between the electronic device and the object (e.g., a time of flight (TOF) sensor). In other examples, the sensor assembly may be a microphone.

As previously discussed, the rear cover assembly 124 includes a cover member 134 (also referred to herein as a rear cover member). In some embodiments, the cover member 134 may be a structurally colored cover member as described herein. The structural color may be present over an entire exterior surface of the cover member or only along present along one or portions of the exterior surface, as described in more detail with respect to FIGS. 4 and 5. A structurally colored cover member 134 may be formed from a glass-based material such as a glass or a glass ceramic material. In other cases, a cover member 134 other than a structurally colored cover member may be formed from a glass material, a glass ceramic material, a polymer material, a ceramic material, or a combination thereof.

In some embodiments, the cover member 134 defines a thicker portion and a thinner portion (as shown in the cross-section view of FIG. 2). In some cases, the thickness of the thicker portion of the cover member is greater than about 1 mm and less than or equal to about 2 mm or about 2.5 mm. The thickness of the thinner portion may be greater than about 0.3 mm and less than about 0.75 mm or greater than about 0.5 mm and less than about 1 mm.

The thicker portion may accommodate one or more components of a sensing array 170. In implementations in which the thicker portion is used to protect one or more sensor modules or components, the thicker portion and/or the protruding region of the thicker portion may be referred to as a sensor feature, a camera feature, a sensing array, a camera panel, and/or a camera bump. For example, the sensing array 170 may include multiple camera assemblies. Each of the camera assemblies may include an optical component such as the optical component 179 or the optical component 176. The optical component 179 may be positioned at least partially within an opening in the thicker portion, as shown for optical component 279 in FIG. 2. The optical component 179 may be a camera module while the optical component 176 may be an illumination module.

The sensing array 170 may include one or more sensor assemblies, such as the sensor assembly 179. In some embodiments, the sensor assembly 179 may include one or more optical modules. For example, the sensor assembly may include an emitter module, a receiver module, or both. In some cases, the sensor assembly 179 may measure a distance to a target, such as a Lidar sensor assembly which is configured to illuminate an object with light and then detect the reflected light to determine or estimate the distance between the electronic device and the object (e.g., a time of flight (TOF) sensor). In some examples the sensor assembly 179 may be positioned below the cover member 134 (and the cover member 134 may act as a window for the sensor assembly 179). In these examples, the optical properties of the cover member 134 may be suitable for use over one or more optical components of the sensor assembly. For example, the one or more optical components may operate over one or more specified wavelength ranges and the cover member 134 may be configured to have a suitable transmission/transmittance over these wavelength ranges. In other examples, the cover member 134 may define an opening over the sensor assembly and an additional cover member may be placed in or over the opening (and act as a window for the sensor assembly).

Each of the front cover assembly 122 and the rear cover assembly 124 is coupled to the enclosure component 110. The enclosure component 110 may at least partially define a side surface of the electronic device 100 and may also be referred to herein as a housing or a housing assembly. An enclosure component used in combination with front and rear cover assemblies as shown in FIGS. 1A and 1B may also be referred to as a band. The enclosure component 110 may include one or more members. In the example of FIGS. 1A and 1B, the enclosure component 110 includes multiple members 112. The members 112 may be formed from a metal material (e.g., one or more metal segments), a glass material, a glass ceramic material, a ceramic material, or a combination of two or more of these materials. The enclosure component 110 also includes one or more dielectric members 114 (e.g., one or more dielectric segments). The dielectric members may be formed from a polymer material, a glass material, a glass ceramic material, a ceramic material, or a combination of two or more of these materials,

As a particular example, the enclosure component 110 may be formed from a series of metal segments (112) that are separated by dielectric segments (114) that provide some extent of electrical isolation between adjacent metal segments (e.g., by preventing electrical conduction through the dielectric segments). For example, a polymer segment (114) may be provided between a pair of adjacent metal segments (112). One or more of the metal segments may be coupled to internal circuitry of the electronic device 100 and may function as an antenna for sending and receiving wireless communication.

The example of FIGS. 1A and 1B is not limited, and in other examples the enclosure component 110 may have a different number of members or may be of unitary construction (e.g., a unibody). In additional examples, the front and rear cover assemblies may at least partially define a side surface of the electronic device. As referred to herein, an enclosure component or member formed from a particular material, such as a metal material, may also include a relatively thin coating of a different material along one or more surfaces, such as an anodization layer, a physical vapor deposited coating, a paint coating, a primer coating (which may include a coupling agent), or the like.

The enclosure component 110 may define one or more openings or ports. In the example of FIGS. 1A and 1B, the enclosure component 110 defines the openings 116 and 117. The opening 116 may allow (audio) input or output from a device component such as a microphone or speaker. The opening 117 may contain an electrical port or connection. In addition, the electronic device 100 may include one or more input devices. In the example of FIGS. 1A and 1B, the input devices 152, 156, and 158 have the form of a button and may extend through additional openings in the enclosure component 110. The input device 154 has the form of a switch. In some cases, the electronic device 100 also includes a support plate and/or other internal structural components that are used to support internal electronic circuitry or electronic components.

In some cases, the enclosure component 110 may include one or more members 115 positioned within a metal member (e.g., 112). In some cases, the member 115 may provide a window for an internal electronic component, may define a portion of a waveguide, and/or allow for beam-forming or beam-directing functionality. For example, the member 115 may define an antenna window for transmitting and receiving wireless signals. The member 115 may be configured to transmit wireless signals at one or more of the frequencies discussed with respect to FIG. 3. For example, the member 115 may be configured to transmit wireless signals at a frequency band between about 25 GHz and about 45 GHz.

The electronic device 100 includes a display 142. The front cover assembly 122 is positioned over the display 142. As previously discussed, the front cover assembly 122 may be substantially transparent or include one or more substantially transparent portions over the display and/or an optical component configured to operate over a visible wavelength range. The enclosure 105 may at least partially surround the display 142 and may enclose the display 142. The display 142 may produce graphical output which is transmitted through a substantially transparent portion of the front cover assembly. In some cases, the display 142 is a touch sensitive display. The display 142 may be a liquid-crystal display (LCD), a light-emitting diode (LED) display, an LED-backlit LCD display, an organic light-emitting diode (OLED) display, an active layer organic light-emitting diode (AMOLED) display, and the like. In some embodiments, the display 142 may be attached to (or may abut) the front cover assembly 122.

The electronic device 100 further includes multiple sensing arrays. As referred to herein, a sensing array may include one or more camera assemblies (e.g., a camera array), one or more sensor assemblies (e.g., a sensor array), an illumination assembly, or combinations of these. In some examples, the front sensing array 118 includes a front-facing camera assembly and a front-facing sensor assembly. The front sensing array may also include another sensor assembly, which in some cases may be an ambient light sensor. In the example of FIGS. 1A and 1B, the rear sensing array 170 includes an array of rear-facing camera assemblies and at least one sensor assembly as described in more detail below.

A sensor assembly may also be referred to herein simply as a sensor. Examples of sensor (assemblies) include, but are not limited to, a proximity sensor, a light sensor (e.g., an ambient light sensor), a biometric sensor (e.g., a face or fingerprint recognition sensor or a health monitoring sensor), a depth sensor, or an imaging sensor. Other examples of sensors include a microphone or a similar type of audio sensing device, a radio-frequency identification chip, a touch sensor, a force sensor, an accelerometer, a gyroscope, a magnetometer such as a Hall-effect sensor or other magnetic sensor, or similar types of position/orientation sensing devices. When the sensor is an optical sensor, the sensor may operate over a particular wavelength range such as a visible, an infrared, or an ultraviolet wavelength range. In some cases, the optical sensor is a reflectance sensor. The electronic device may further include a processing unit (also, processor) that computes a value based on a signal from the sensor.

An array of camera assemblies (also referred to herein as a camera array) typically includes multiple camera modules and one or more illumination modules. When the camera array includes multiple camera modules, each of the camera modules may have a different field of view or other optical property. For example, a camera module may be configured to produce an image from visible light or infrared light. The multiple camera modules may be also referred to as a set of camera modules and in some cases may form an array of camera modules. In some cases, a camera module includes an optical sensor array and/or an optical component such as a lens, filter, or window. In additional cases, a camera module includes an optical sensor array, an optical component, and a camera module housing surrounding the optical sensor array and the optical components. The camera module may also include a focusing assembly. For example, a focusing assembly may include an actuator for moving a lens of the camera module. In some cases, the optical sensor array may be a complementary metal-oxide semiconductor (CMOS) array or the like. The illumination module may be part of an illumination assembly that includes a light source such as a flood light source or other emitter which enables various sensing modes like face recognition and digital photography. For example, one or more emitters may emit an array of beams that are reflected off various parts of the face. The reflected beams can be used to create a point or depth map of the face and used to authenticate a user.

Optical modules included in the sensing array may include a photodetector and/or image sensor, associated electronics, one or more optical lenses, optical covers, barrels, or shrouds and associated optical elements. For example, the optical module may be a camera module, an illumination module, or a sensor module. The sensing array may define any number of optical modules such as one, two, three, four, five, or six optical modules.

In addition, the electronic device 100 may include one or more device components that may be part of a wireless communication system, such as the device components 381, 383, and 385 shown in the cross-section view of FIG. 3. As examples, the wireless communication system may be an RF or an IR communication system. In some cases, the device components are wireless transmission modules that may include one or more antenna assemblies, also referred to herein simply as antennas. An RF communication system may operate at one or more of a “low band” (e.g., less than 1 GHz, such as about 400 MHz to less than 1 GHz, about 600 MHz to about 900 MHz, or 600 MHz to 700 MHz), a “mid-band” frequency range (e.g., about 1 GHz to about 6 GHz, such as about 1 GHz to about 2.6 GHz, about 2 GHz to about 2.6 GHz, about 2.5 GHz to about 3.5 GHz, or about 3.5 GHz to about 6 GHz), or a″ high-band” frequency range (e.g., about 24 GHz to about 40 GHz, about 57 GHz to about 64 GHz, or about 64 GHz to about 71 GHz), or a frequency range from about 1 GHz to about 10 GHz. As previously discussed, a component of an RF communication system may include an RF antenna configured to radiate a radio-frequency (RF) signal. The RF antenna may be configured to operate at one or more desired RF frequency ranges or RF frequency bands.

In some cases, the electronic device 100 may include one or more groups of antennas that include elements that are configured to communicate via a 5G wireless protocol (including millimeter wave and/or 6 GHz communication signals). 5G communications may be achieved using various different communications protocols. For example, 5G communications may use a communications protocol that uses a frequency band below 6 GHz (also referred to as the sub-6 GHz spectrum). As another example, 5G communications may use a communications protocol that uses a frequency band above 24 GHz (also referred to as the millimeter-wave spectrum). Further, the particular frequency band of any given 5G implementation may differ from others. For example, different wireless communications providers may use different frequency bands in the millimeter-wave spectrum (e.g., one provider may implement a 5G communications network using frequencies around 28 GHz, while another may use frequencies around 39 GHz). The antenna group(s) may be configured to allow communications via one or multiple of the frequency bands that implement 5G communications. Alternately or additionally, the electronic device may include one or more antennas that operate in a 3G frequency band, a 4G frequency band, a GPS frequency band (such as an L1, L2, or a L5 frequency band), a WIFI frequency band, or the like.

In some cases, the electronic device 100 includes one or more directional antennas (or high gain antennas). Accordingly, the antenna gains of the directional antennas may be highest along particular directions. A directional antenna may include an array of transceiver elements that are used to form the shapes and orientations of the radiation patterns (or lobes) of the antenna, which may be a millimeter wave antenna. The electronic device 100 may include multiple directional antennas which have different primary transmission directions, as explained further with respect to FIG. 3.

FIG. 2 shows a partial cross-section view of an electronic device. The electronic device 200 includes an enclosure 205 which comprises a front cover assembly 222 and a rear cover assembly 224. One or both of the front cover assembly 222 or the rear cover assembly 224 may include a structurally colored cover member as described herein. FIG. 2 may be an example cross-sectional view along A-A of FIG. 1B and the front cover assembly 222 and the rear cover assembly 224 and their respective elements may be as previously described with respect to FIGS. 1A and 1B.

The electronic device 200 includes a sensing array 270 located at the rear of the electronic device 200. The sensing array 270, which may also be described as a rear-facing sensing array, includes rear-facing optical modules 276 and 279. In the example of FIG. 2, the rear-facing optical modules 276 and 279 are part of a rear-facing camera array 275. For example, the optical module 276 may be an illumination module and the optical module 279 may be a camera module. The optical module 279 may be configured to operate over a visible wavelength range. At least some elements of the camera array 275 are positioned within the internal cavity 201 of the electronic device. The electronic device 200 may also include a component of a wireless communication and/or charging system, as previously described with respect to FIGS. 1A and 1B and illustrated in FIG. 3. A wireless charging coil or other wireless charging component of the electronic device may be configured to receive wireless power from an external power supply through the cover member of the rear cover assembly

The front cover assembly 222 includes a cover member 232, a display 264, and a touch sensor 262. The electronic device also includes an enclosure component 210 which defines a side surface of the electronic device. The enclosure component may include a member 212.

The rear cover assembly 224 includes a cover member 234. In the example of FIG. 2, the rear cover member 234 does not extend over the optical modules 276 and 279. Instead, the cover member 234 defines through-holes 267 and 268 and the optical modules 279 and 276 extend at least partially into these through-holes. A window 287 extends over the optical modules 279 and over the through-holes 267. The window 287 may be formed of a transparent glass ceramic, or a transparent ceramic such as sapphire, or glass. The rear cover member 234 may also extend over a component of a wireless communication and/or charging system, as previously described with respect to FIGS. 1A and 1B and illustrated in FIG. 3. The cover assembly 224 defines an interior surface 242 and an exterior surface 244.

In the example of FIG. 2, the cover assembly 224 includes a thicker portion 227 and a thinner portion 225 and the sensing array 270 is generally located in the vicinity of the thicker portion 227. The thicker portion 227 is at least partially defined by a thicker portion 237 of the cover member 234 and the thinner portion 225 is at least partially defined by a thinner portion 235 of the cover member 234. In some embodiments where the cover member 234 is a structurally colored cover member, the optical properties of the thicker portion 237 of the cover member 234 vary from those of the thinner portion 235. For example, an average transmission over the visible range may be greater in the thinner portion 235 than in the thicker portion 237. For example, the cover member 234 may have a transmission ranging from 35% to 95%, from 35% to 90%, from 60% to 95%, or from 65% to 90% over a visible light range (e.g., 360 nm to 740 nm), which may be measured for the thicker portion 237. In addition, a color of the thicker portion 237 may be different from that of the thinner portion 235

The thicker portion 227 also defines a feature 257 that protrudes with respect to the thinner portion 225. The feature 257 is also referred to generally herein as a protruding region, as a protruding feature, as a plateau region or feature, or as a bump. The thinner portion 225 of the cover assembly 224 defines an exterior surface 226 (also referred to herein as a base surface). The thicker portion 227 of the cover assembly 224 defines an exterior surface 228 (also referred to herein as a raised surface or top surface). As an example, the exterior surface 228 may substantially define a plateau. Such an exterior surface may also be referred to herein as a (raised) plateau surface. The feature 257 protrudes with respect to the exterior surface portion 226.

In the example of FIG. 2, the through-holes 267 and 268 extend through the thicker portion 227 of the cover assembly 224. The size of through-holes 267 and 268 is exaggerated for convenience of illustration. Openings to the holes are located in the exterior surface 228. The through-holes may be referred to as a set of through-holes and in some cases may define an array of through-holes. Similarly, the openings may be referred to as a set of openings and in some cases may define an array of openings. A module such as a camera module, a sensor module, or an illumination module may be positioned below or within each opening of the set of openings. In addition, at least some of the modules may extend into respective through-holes of the set of through-holes. An end of one or more of the modules may project beyond the exterior surface 228.

The camera array 275 further includes a support structure 271. The support structure 271 may be configured to hold various elements of the camera array 275 in place. For example, each of the optical modules 276 and 276 may be mounted to the support structure 271. In the example of FIG. 2, the support structure 271 includes a bracket 272 that is coupled to an interior surface of the cover assembly 224. In the example of FIG. 2, the support structure 271 also includes a frame 273 which nests at least partially within the bracket 272 and supports a circuit assembly 274, which may be mounted on a printed circuit board. However, this example is not limiting and in additional embodiments the support structure may have a different form.

As shown in FIG. 2, an internal coating 260 is disposed along an interior surface 252 of the cover member 234. In some embodiments, an external coating, such as a smudge resistant coating, may be disposed along an exterior surface of the cover member 234 as previously described with respect to FIG. 1B. The optical properties of the coating 260 may influence the optical properties of the rear cover assembly. For example, the coating may affect the amount of light transmitted back through the cover member to a viewer and thus may be termed an optical coating. In some embodiments, the coating 260 is configured to at least partially reflect visible light transmitted through the rear cover member and incident on the coating. In other words, the coating 260 is at least partially reflective. Reflection of visible light from the coating sends the reflected light back through the cover member. The reflected light exiting the cover member (and the cover assembly) produces the perceived color of the cover assembly.

The coating need not be mirror-like in order for its optical properties to influence the optical properties of the cover assembly. As one example, a partially reflective coating may simply be white or light in color. In addition, the coating 260 may adsorb at least some wavelengths of light transmitted through the rear cover member 234 and incident on the coating and thus may influence the spectrum or light reflected back through the rear cover member 234. In some cases, the spectrum of light reflected from the coating is similar to that incident on the coating (e.g., for a neutral coating having a* and b* near zero). In additional cases, the coating selectively absorbs some of the incident light, so that the color of the rear cover assembly 224 may differ from that of the rear cover member 234 (without the coating). For example, the perceived color of the rear cover assembly 224 may differ in chroma and/or hue from the color of the rear cover member 234.

The coating 260 may include a color layer, a multilayer interference stack, or both. When the coating includes both a color layer and a multilayer interference stack, the perceived color of the rear cover assembly 224 may be different in regions where the multilayer interference stack is present than in regions free of the multilayer interference stack. A color layer may be polymer based and include a colorant (e.g., a pigment or dye). As used herein, a color layer may have a distinct hue or may be near neutral in color (with a* and b* near zero, e.g., white). The coating 260 may include multiple polymer-based layers, at least one of which is a color layer. The coating 260 may include an optically dense layer, which may be placed behind a color layer or a multilayer interference stack. In some cases, the coating as a whole may be optically dense.

When the coating 260 includes a multilayer interference stack, the multilayer interference stack may be used to define a decorative logo or other symbol. The multilayer interference stack may include multiple dielectric layers, the multiple layers configured to produce optical interference. The multilayer interference stack may also be referred to herein as an optical interference stack or an optical interference coating (or coating element). For example, the multilayer interference stack may include a first layer comprising a first inorganic dielectric material and a second layer comprising a second inorganic dielectric material. For example, the coating may comprise a metal oxide, a metal nitride, and/or a metal oxynitride. Suitable metal oxides include, but are not limited to, a silicon oxide (e.g., SiO₂), niobium oxide (e.g., Nb₂O₅), titanium oxide (e.g., TiO₂), tantalum oxide (e.g., Ta₂O₅), zirconium oxide (e.g., ZrO₂), magnesium oxide (e.g., MgO), and the like. Suitable metal nitrides include, but are not limited to, silicon nitride (SiNₓ), silicon oxynitride (e.g., SiOₓN_{y}) and the like. The layers of the first and second inorganic dielectric materials may be thin and may be deposited using physical vapor deposition or a similar technique. The description of the coating 260 is generally applicable herein and not limited solely to the example of FIG. 2.

The cover member 234 may be positioned over one or more internal components of the electronic device 200 and may also be configured to allow transmission of electromagnetic signals to and/or from the internal component. As an example, one or more regions of a structurally colored cover member 234 may be configured to be RF-transmissive and may have a dielectric constant suitable for use over a radio-frequency antenna or wireless charging system. In some cases, the material or combination of materials of the cover member 234 may have a dielectric constant (also referred to as the relative permittivity) having a value from 3 to 7, 4 to 8, 4 to 6.5, 5 to 7, 5 to 6.5, 5.5 to 7.5, 5.5 to 7, or 6 to 7 in a radio frequency band. In some cases, these values are maximum values while in other cases these values are measured at the frequency range(s) of interest. As an example, the frequency range of interest may be from about 5 GHz to about 45 GHz, or from 25 GHz to 45 GHz. These values may be measured at room temperature. As a further example, the material of the cover member 234 may have a magnetic permeability sufficiently low that it does not interfere with transmission of magnetic fields generated by the inductive coupling wireless charging system. In some cases, the cover member 234 may be substantially non-magnetic.

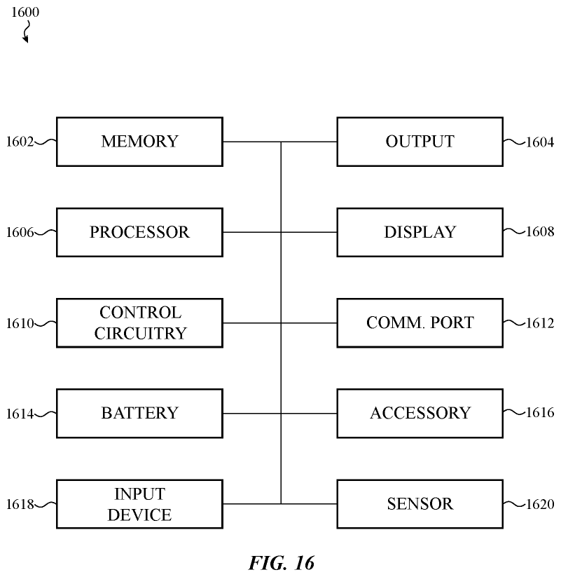

FIG. 3 shows another partial cross-section view of an electronic device. As shown in FIG. 3, the electronic device 300 includes internal device components 381, 382, and 383 positioned within an internal cavity 301. As an example, the device components 381 and 383 may be part of a wireless communication system and the device component 382 may be part of a wireless charging system. In some cases, the electronic device 300 may include an additional device component that is part of the wireless communication system (not shown in this cross-section), which may be similar to the components described with respect to FIGS. 1A and 1B. Additional device components 399 are indicated schematically with a dashed line and may include one or more of the components described with respect to FIG. 16. FIG. 3 may be an example of a partial cross-sectional view along B-B of FIG. 1B.

The enclosure 305 of the electronic device 300 includes a cover assembly 322 comprising a cover member 332. The cover member 332 extends over the internal device component 381 and may be a front cover member. The electronic device also includes a display 364, which may include a touch sensing layer. The enclosure 305 also includes a cover assembly 324 comprising a cover member 334. The cover member 334 extends over the internal device components 382 and 383 and may be a rear cover member. An internal coating 360 is coupled to an interior surface of the cover member 334. The cover assembly 322 and the cover assembly 324 are coupled to a member 312b of an enclosure component 310. The coating 360 may be similar in composition and optical properties to the coating 260 and for brevity that description is not repeated here.

The device component 383 may be part of a wireless communication system and in some cases may be a directional antenna (assembly). By the way of example, the device component 383 may have a primary transmission direction which is substantially perpendicular to the rear surface of the electronic device. The cover member 334 may therefore be configured to provide electrical properties suitable for use over the component of a wireless communication system. For example, the cover member 334 may be a dielectric cover member and may be formed from a material having a dielectric constant and a dissipation factor sufficiently low to allow transmission of RF or IR (e.g., near-IR) signals through the cover member. The cover member 334 may have similar dielectric properties to the cover member 234 and the cover member 134 and for brevity that description not repeated here. The device component 381, as well as the device component 383 may be similar to the wireless communication system device components described with respect to FIGS. 1A and 1B and may be operated at similar frequency ranges. For example, the device components 381 and 383 may be compatible with a 5G wireless protocol (including millimeter wave and/or 6 GHz communication signals). In some cases, the device components 381 and 383 may be configured to transmit wireless signals at a frequency band between about 25 GHz and 45 GHz.

When the device component 382 is part of an inductive coupling wireless charging system, the cover member 334 may also be configured to have a magnetic permeability sufficiently low that it does not interfere with transmission of magnetic fields generated by the inductive coupling wireless charging system. For example, the component of an inductive coupling wireless charging system may include a wireless receiver component such as a wireless receiver coil or other feature of the wireless charging system.

The device component 381 may also be part of a wireless communication system and in some cases may be a directional antenna (assembly). By the way of example, the device component 381 may have a primary transmission direction which is substantially perpendicular to the front surface of the electronic device. The cover member 332 may therefore be configured to provide electrical properties suitable for use over the component of a wireless communication system and may have electrical properties similar to those described with respect to the cover member 334 and may have one or more optical properties similar to those previously described with respect to the cover member 132 of FIG. 1A.

FIG. 4 shows an example enclosure component for an electronic device. The enclosure component 434 may be an example of the rear cover member 134 of FIG. 1B. The enclosure component 434 includes a thicker portion 437 and a thinner portion 435. The thicker portion 437 may be positioned over a sensor assembly, which may include multiple camera modules. As shown in the example of FIG. 4, the thicker portion defines through-holes, which can accommodate components of the sensor assembly as previously described with respect to FIG. 2. The thinner portion 435 may be positioned over an internal electronic component of the electronic device such as a wireless charging assembly, an antenna component, or the like. In some cases, such as in the example of FIG. 4, the thinner portion 437 includes a central portion of the enclosure component.

As previously discussed, the enclosure component 434 may be structurally colored at least in part due to a surface region that includes a modified glass-based material. This surface region may therefore also be referred to herein as a modified surface region. The enclosure component 434 may be formed at least in part by modifying a surface zone of a workpiece that is formed from the glass-based material. As an additional example, the workpiece may include a glass-based portion and a surface zone of this glass-based portion may be modified. The glass-based material may be a glass material, a glass-ceramic material, or a combination of these.

The modified glass-based material typically has a structure that differs from that of the unmodified glass-based material of the workpiece. For example, the modified glass-based material may include structural features such pores, crystals, a phase separated structure, or the like that are not present in the unmodified glass-based material or that are present in the unmodified glass-based material in a different form and/or amount. In some examples, the modified glass-based material has a lower effective index of refraction than the unmodified glass-based material. Cross-section views of example cover members showing these surface regions and the underlying regions of the cover members are shown in FIGS. 5 through 12.

The modification of the glass-based material may be achieved using one of several techniques. For example, pores may be created within the glass-based material by laser etching, chemical etching, chemical leaching, electrochemical etching, or the like. Various heat treatment techniques may be used to crystallize, vitrify, or create a phase-separated structure within the glass-based material, as described in more detail below.

In some embodiments, the surface region including the modified glass-based material may extend over an entire exterior surface of the cover member. With respect to the example of FIG. 4, the surface region may extend over both the thicker and the thinner portions of the cover member. In other embodiments, the surface region including the modified glass-based material extends only along a portion of the exterior surface. With respect to the example of FIG. 4, the surface region may extend over the thicker region, but may not extend over the thinner region, or vice versa.

In some embodiments, the structurally colored enclosure component also includes a coloring agent. The coloring agent may be present in the surface region, the substrate region, or both. In these embodiments, the color of the enclosure component may be due to the combination of the structural color and the color agent. In some examples, the coloring agent may be an element that is incorporated into a glass phase and/or a crystalline phase of the material, such as a rare earth element or a transition metal element. In other examples, the coloring agent may form a distinct nanophase within a glass and/or a crystalline phase of the material. In some examples, the coloring agent takes the form of metallic nanoparticles, which may be formed of one or more metals. For example, the metallic nanoparticles may be formed from one or more transition metals such as titanium, chromium, vanadium, manganese, iron, cobalt, nickel, copper, silver, gold, and the like. The nanoparticles may have a size less than 1 micrometer, such as from 10 nm to less than 1 micrometer, from 15 nm to 200 nm, from 15 nm to 100 nm, from 25 nm to 100 nm, from 50 nm to 150 nm, from 50 nm to 150 nm, or from 100 nm to 200 nm. In some embodiments, a second set of metallic nanoparticles in the surface region (e.g., in the second layer) has an average size larger than an average size of a first set of metallic nanoparticles in the substrate region (e.g., in the first layer). For example, the metallic nanoparticles of the second set may have an average size greater than or equal to 140 nm, such as an average size from 140 nm to less than 1 micrometer, to cause scattering of light from the surface region. Each of the first and the second sets of metallic nanoparticles may contribute to a color of the cover member and the cover assembly. In some examples, metallic nanoparticles may have a generally rounded shape, such as a spherical shape, or an elongated shape, such as a prolate spheroid. This description of coloring agents applied generally to the disclosure herein and is not intended to be limited to the example of FIG. 4. As specific examples, the metal of the metallic nanoparticles may be present at a concentration from 0.01 mol % to 2 mol %, from 0.5 mol % to 2 mol %, from 0.5 mol % to 5 mol %, from greater than 5% to 10 mol % or from greater than 7 mol % to 10 mol %.

The color of an enclosure component may be characterized in several ways. For example, the color of a component may be characterized by coordinates in CIEL*a*b* (CIELAB) color space. In CIEL*a*b* (CIELAB) color space, L* represents brightness, a* the position between red/magenta and green, and b* the position between yellow and blue. Alternately or additionally, the color of a cover assembly may be characterized by coordinates in L*C*h* color space, where C* represents the chroma and hab represents the hue angle (in degrees). The chroma C* is related to a* and b* as C*=\sqrt{(a*)²+(b*)²}. In addition, the hue angle h_{ab} is related to a* and b* as

$${h}_{ab} = {tan}^{- 1} \frac{b *}{a *} .$$

A broadband or semi-broadband illuminant may be used to determine the color of a portion of the cover member or cover assembly. For example, a CIE illuminant or other reference illuminant may be used. In some cases, the color of the cover member may be determined from light transmitted through the cover member. In additional cases, the color of a cover member may be determined from light reflected back through the cover member (e.g., using a white background). The CIELAB or L*C*h coordinates for a given illuminant can be measured with a device such as a colorimeter or a spectrophotometer or calculated from transmission or reflectance spectra.

In some examples, a color of an enclosure component is characterized by an a* value having a magnitude greater than or equal to 0.25, greater than or equal to 0.5, greater than or equal to 0.75, or greater than or equal to 1. In additional examples, the color of the enclosure component is characterized by a b* value having a magnitude greater than or equal to 1, greater than or equal to 1.5, or greater than or equal to 2. In further examples, the color of the enclosure component may have an L* value of at least 20, at least 80, at least 85, or at least 90. The color of the enclosure component may be characterized by having a C* value greater than 1.75, greater than 2, or greater than 2.5. When a color difference between two different portions of the enclosure component is desired, a chroma difference (ΔC*) between the two different portions may be at least 1, at least 2, at least 5, at least 10, at least 15, at least 20, at least 25, or ranging from 1 to 10, 5 to 20, or 15 to 50.

FIG. 5 shows a partial cross-section view of an enclosure component. The cover member 534 is a structurally colored enclosure component that includes a modified surface region 552 which extends along and defines an exterior surface 542 of the cover member. An underlying region 554, which is also referred to herein as a substrate region, defines an interior surface 544 of the cover member. The cover member 534 may be an example of the enclosure component 434 and the cross-section view of FIG. 5 may be an example of a cross-section along C-C in detail area 1-1 of FIG. 4.

In the example of FIG. 5, the surface region 552 defines a thickness t₅ that is less than a thickness T₅ of the cover member 534. The thickness of the surface region 552 may depend upon the mechanism by which the structural color is created. For example, when the surface region of the enclosure component defines a thin film that produces an optical effect through interference of light reflected from the surface of the surface region and light reflected from interface between the surface region and the underlying substrate, the thickness of the surface region may be less than 5 micrometers or less than 1 micrometer. However, the thickness of the surface region may be larger than this when interaction of light with structural features having different refractive indices within the surface region contributes to the optical effect. The thickness of the surface region 552 is enlarged in FIG. 5 for convenience of illustration.

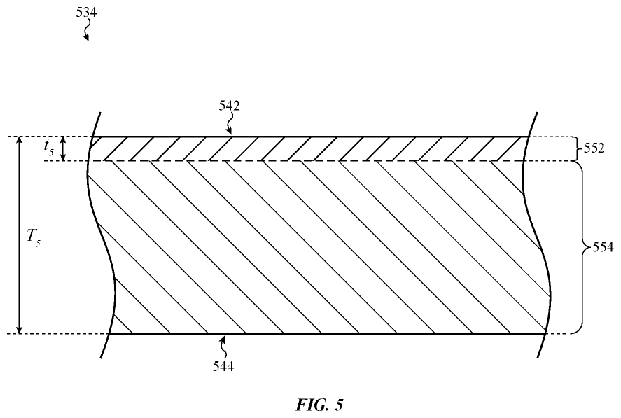

As previously discussed, the modified glass-based material typically has a structure that differs from that of the unmodified glass-based material of the workpiece. In some cases, the substrate region 554 may comprise a first glass-based material and the surface region 552 may comprise a second glass-based material that is different from the first glass-based material. In some cases, the second glass-based material may be described as being derived from the first glass-based material. The second glass-based material may differ from the first glass-based material in terms of the size, shape, or composition of one or more components of the glass-based material as described in more detail below with respect to FIGS. 6-10. In some embodiments, the first glass-based material may define the substrate region and the second glass-based material may define the surface region. The first glass-based material of the substrate region 554 may define a first layer and the second glass-based material of the surface region 552 may define a second layer that defines an exterior surface of the cover member.

In some embodiments, the size of the structural features within the surface region 552 depends upon the mechanism by which the structural color is created. For example, when the surface region defines a thin film, the size and/or spacing of structural features within the surface region 552 may be much smaller than wavelengths of visible light within the surface region so that the internal structure of the surface region defines an effective medium for light traveling through the surface region. However, when the interaction of light with structural features within the surface region 552 contributes to the structural color, the size and/or spacing of the structural features within the surface region may be larger. For example, the size and/or spacing of the structural features within the surface region may be generally on the order of one or more wavelengths of visible light within the surface region. When the surface region 552 includes regularly repeating regions of higher and lower refractive index, the repeating regions may have a periodicity of at least half the wavelength of visible light within the surface region. For reference, a wavelength of light within the surface region may be equal to the wavelength of light in a vacuum (about 400 nm to about 800 nm for visible light) divided by a refractive index within the surface region

The cover member 534 may produce an iridescent effect through one or more mechanisms. As previously discussed, in embodiments where the surface region 552 defines a thin film through interference of light reflected from the surface of the surface region and light reflected from interface between the surface region and the underlying substrate, the surface region 552 and the underlying substrate region 554 may act together to produce an optical effect. The surface region 552 may have an effective refractive index less than a refractive index of the substrate region 554 and in some cases the difference in effective refractive index may produce an iridescent effect. For example, the second layer defined by the second glass-based material of the surface region 552 may have a second index of refraction that is less than a first index of refraction of the first layer defined by the first glass-based material of the substrate region 554. Alternately, interfaces between different phases having different refractive indices within the surface region 552 may be configured to produce an iridescent effect through interference or diffraction. As a further example, regularly repeating regions of higher and lower refractive index within the surface region 552 may define a photonic crystal and produce the desired structural color.

In some embodiments, the first glass-based material of the substrate region 554 and the second glass-based material of the surface region 552 are each a glass material. In some instances, the glass material is a silicate glass, such as an aluminosilicate glass, a boroaluminosilicate glass, or an aluminophosphosilicate glass. As used herein, an aluminosilicate glass includes the elements aluminum, silicon, and oxygen, but may further include other elements. Similarly, a boroaluminosilicate glass includes the elements boron, aluminum, silicon, and oxygen, but may further include other elements. An aluminophosphosilicate glass includes the elements aluminum, phosphorous, silicon, and oxygen, but may further include other elements. For example, an aluminosilicate glass, a boroaluminosilicate glass, or an aluminophosphosilicate glass may further include monovalent or divalent ions which compensate charges due to replacement of silicon ions by aluminum ions. Suitable monovalent ions include, but are not limited to, alkali metal ions such as Li⁺, Na⁺, or K⁺, such as in alkali aluminosilicate glass. Suitable divalent ions include alkaline earth ions such as Ca²⁺ or Mg²⁺, such as in an alkaline earth aluminosilicate glass. In embodiments, the glass material is ion exchangeable. In additional examples, the aluminosilicate glass, the boroaluminosilicate glass, or the aluminophosphosilicate glass may further include dopants for the reinforcing phase(s) to be formed in the composite component (such as metal ions). In some examples, the aluminosilicate glass or a boroaluminosilicate glass may further include elements which stabilize the dopants during the melting process to allow formation of the reinforcing phase during a later heat treatment phase. In some embodiments, the silicate glass may be substantially free of tungsten or molybdenum (e.g., formed from a composition that is substantially free of tungsten oxide and/or molybdenum oxide). In some embodiments, the silicate glass may be substantially free of a conventional ultraviolet (UV) light activated photosensitizing agent for nucleation of metallic nanoparticles.

In some embodiments, the first glass-based material of the substrate region 554 and the second glass-based material of the surface region 552 are each a glass ceramic material. In additional instances, the first and/or the second glass-based material is a glass ceramic material or a combination of a glass material and a glass ceramic material. As referred to herein, a glass ceramic material comprises one or more crystalline phases (e.g., crystals) formed by crystallization of a (precursor) glass material. In some cases, the crystalline phases are in the form of ceramic nanoparticles. These crystalline phases can contribute to the favorable mechanical properties of the glass ceramic material. The glass ceramic may further comprise an amorphous (glass) phase and the crystals may be dispersed in the glass phase. In some examples, the amount of the crystalline phase(s) is greater than 10%, from 20% to 90%, from 30% to 90%, from 40% to 90%, from 50% to 90%, from 60% to 90%, from 70% to 90%, from 20% to 40%, from 20% to 60%, from 20% to 80%, from 30% to 60%, or from 30% to 80% of the glass ceramic by weight. In some cases, these values may correspond to an average amount or a local amount of crystalline phase(s) in the glass ceramic component. The residual glass phase may form the balance of the material.

By the way of example, the glass ceramic material may be an alkaline silicate, an alkaline earth silicate, an aluminosilicate, a boroaluminosilicate, an aluminophosphosilicate, a perovskite-type glass ceramic, a silicophosphate, an iron silicate, a fluorosilicate, a phosphate, or a glass ceramic material from another glass ceramic composition system. In some embodiments, the glass ceramic material comprises an aluminosilicate glass ceramic or a boroaluminosilicate glass ceramic. Aluminosilicate glasses can form several types of crystalline phases, including β quartz solid solution crystals, keatite solid solution crystals (β spodumene solid solution crystals), petalite crystals, lithium disilicate crystals, and various other silicates. Other silicates include, but are not limited to, silicates including aluminum and optionally other elements such as lithium, sodium, potassium, and the like. Examples of such silicates include lithium orthoclase, lithium orthosilicate, (Li, Al, Na) orthosilicates (e.g., α or β eucryptite), and lithium metasilicate.

In addition to the principal elements of the glass ceramic material (e.g., aluminum, silicon, and oxygen for an aluminosilicate) the glass ceramic material may also include other elements. For example, the glass ceramic material (and the precursor glass) may include elements from nucleating agents for the glass ceramic material, such as a metal oxide (Ti, Zr) or other suitable oxide material. Aluminosilicate and boroaluminosilicate glass ceramics may further include monovalent or divalent ions similar to those described for aluminosilicate and boroaluminosilicate glasses. Suitable monovalent ions include, but are not limited to, alkali metal ions such as Li⁺, Na⁺, or K⁺. Suitable divalent ions include alkaline earth ions such as Ca²⁺ or Mg²⁺. The glass ceramic material may be ion exchangeable. In additional examples, the glass ceramic may further include dopants for the reinforcing phase(s) to be formed in the composite component (such as metal ions).

In some cases, the glass-based material is chemically strengthened by ion exchange. For example, an ion-exchangeable glass or glass ceramic material may include monovalent or divalent ions such as alkali metal ions (e.g., Li⁺, Na⁺, or K⁺) or alkaline earth ions (e.g., Ca²⁺ or Mg²⁺) that may be exchanged for other alkali metal or alkaline earth ions. If the glass or glass ceramic material comprises sodium ions, the sodium ions may be exchanged for potassium ions. Similarly, if the glass or glass ceramic material comprises lithium ions, the lithium ions may be exchanged for sodium ions and/or potassium ions. Exchange of smaller ions in the glass or glass ceramic material for larger ions can form a compressive stress layer along a surface of the glass or glass ceramic material. Formation of such a compressive stress layer can increase the hardness and impact resistance of the glass or glass ceramic material.

FIG. 6 shows another partial cross-section view of an enclosure component. The cover member 634 is a structurally colored enclosure component that includes a modified surface region 652 which extends along and defines an exterior surface 642 of the cover member. An underlying region 654, which is also referred to herein as a substrate region, defines an interior surface 644 of the cover member. The cover member 634 may be an example of the enclosure component 434 and the cross-section view of FIG. 6 may be an example of a cross-section along C-C in detail area 1-1 of FIG. 4.

As schematically illustrated in FIG. 6, the surface region 652 includes pores 664 and the substrate region 654 lacks the pores. In other words, the substrate region 654 is substantially non-porous. Therefore, the internal structure of the surface region 652 is modified from the internal structure of the substrate region 654 by the addition of the pores 664. In some embodiments, the pores 664 may improve mechanical performance of the enclosure component by acting as stress concentrators. For example, when the enclosure component experiences an impact, the energy due to the impact may be dissipated by collapse of the pores 664 rather than crack propagation.

As previously discussed with respect to FIG. 5, the size of the pores 664 within the surface region 652 may depend upon the mechanism by which the structural color is created. In some examples, the average size of the pores is smaller than wavelengths of visible light within the surface region so that the internal structure of the surface region defines an effective medium for light traveling through the surface region. As examples, the pores may have an average size that is greater than zero and less than 50 nm, greater than zero and less than 25 nm, or greater than zero and less than 10 nm. In some cases, pores exposed to the surface may range between 1 nm and 100 nm in diameter. In some cases, the void volume fraction of the porous layer may be greater than 10% and less than 90%, greater than 10% and less than 75%, and greater than 10% and less than 50%. In other examples, the size of the pores 664 may be generally on the order of one or more wavelengths of visible light within the surface region. The pores may have any shape, including a cylindrical shape. The internal pore wall may be smooth, may be rugate, or may have a periodic structure. In the example of FIG. 6, the pores 664 are distributed in a matrix of the glass-based material 662. The average refractive index of the surface region 652 may be less than the average refractive index of the substrate region 654 due to the pores 664. The size of the pores 664 is enlarged for convenience of illustration, and the shape, the average volume fraction, and the distribution of the pores shown in FIG. 6 is exemplary rather than limiting.

As shown in FIG. 6, the substrate region 654 is formed of a first glass-based material 668 and the surface region includes a second glass-based material 662 that is different from the first glass-based material. The pores 662 are distributed within a matrix of the second glass-based material 662. The first glass-based material 668 and the second glass-based material 662 may differ in internal structure, chemical composition, or both. For example, the second glass-based material 668 may have a different composition than the first glass-based material 662 when the pores are formed by a chemical process such as a selective leaching process, an etching process, or a burning off process that can leave a glassy relic structure. In some examples, both the first glass-based material and the second glass-based materials are silicate glass materials. In the example of FIG. 6, the substrate region 654 may be described as being defined by the first glass-based material 668 and the surface region 652 may be described as being defined by the second glass-based material 662 even though the surface region 652 is porous and the surface region 652 and/or the substrate region 654 may also include one or more coloring agents.

The surface region 652 defines a thickness t₆ that is less than a thickness T₆ of the cover member 634. The thickness of the surface region 652 may depend upon the mechanism by which the structural color is created in a similar manner as previously discussed with respect to FIG. 5. In some examples, the thickness of the porous layer is greater than 20 nm, such as greater than 20 nm and less than 100 microns or greater than 20 nm and less than 250 microns.

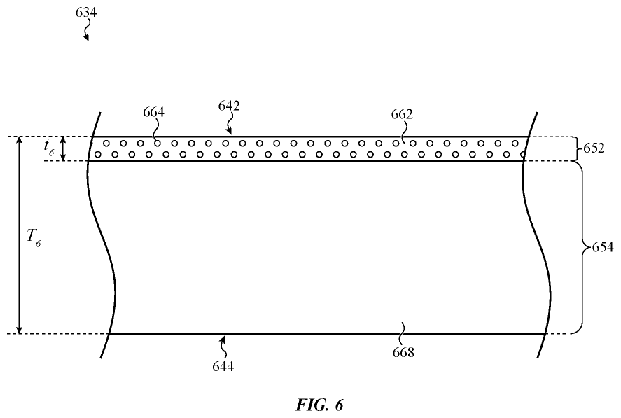

FIG. 7 shows another partial cross-section view of an enclosure component. The cover member 734 is a structurally colored enclosure component that includes a modified surface region 752 which extends along and defines an exterior surface 742 of the cover member. An underlying region 754, which is also referred to herein as a substrate region, defines an interior surface 744 of the cover member. The cover member 734 may be an example of the enclosure component 434 and the cross-section view of FIG. 7 may be an example of a cross-section along C-C in detail area 1-1 of FIG. 4.

As schematically illustrated in FIG. 7, the surface region 752 includes crystals 764 and the substrate 754 is substantially free of the crystals. The crystals 764 may also be referred to herein as particles. Therefore, the internal structure of the surface region 752 is modified from the internal structure of the substrate region 754 by the addition of the crystals 764. As previously discussed with respect to FIG. 5, the size of the crystals 764 within the surface region 752 may depend upon the mechanism by which the structural color is created. In some examples, the average size of the crystals 764 is smaller than wavelengths of visible light within the surface region so that the internal structure of the surface region defines an effective medium for light traveling through the surface region. For example, the crystals 764 may have an average size that is greater than zero and less than or equal to 100 nm, from 20 nm to 100 nm, from 30 nm to 100 nm, greater than zero and less than 50 nm or greater than zero and less than 25 nm. In other examples, the size of the crystals 764 may be larger than 100 nm and in some cases may be generally on the order of one or more wavelengths of visible light within the surface region. The size of the crystals 764 is enlarged for convenience of illustration, and the shape, the average volume fraction, and the distribution of the crystals shown in FIG. 7 is exemplary rather than limiting. In further examples, the crystals may form an assembly that helps to produce the desired optical effect, such as a multi-layered or other suitable structure.

As shown in FIG. 7, the substrate region 754 is formed of a first glass-based material 768 and the surface region includes second glass-based material 762 that is different from the first glass-based material. In the example of FIG. 7, the crystals 764 are distributed in a matrix of the second glass-based material 762 and the surface region 752 may be a glass ceramic region. The average refractive index of the surface region 752 may be different than the average refractive index of the substrate region 754 due to the crystals 764. For example, the refractive index difference between the crystals 764 and the matrix of the second glass-based material 762 may be greater than 0.1. To minimize haze, the amount of interface between the crystals 764 and the second glass-based material 762 may be minimized (e.g., the crystals may be configured to minimize branching structures). The first glass-based material 768 and the second glass-based material 762 may differ in internal structure, chemical composition, or both. For example, the second glass-based material 762 may have a different composition than the first glass-based material 768 due to the formation of the crystals 764. In some examples, both the first glass-based material and the second glass-based materials are silicate glass materials. In some cases, the crystals may be ceramic crystals such as any of the glass ceramic crystalline phases previously discussed with respect to FIG. 5. In some cases, the crystals may be semiconducting crystals such as metal oxide semiconductor crystals. Examples of metal oxide semiconductors include, but are not limited to, a zinc oxide (e.g., ZnO or ZnO₂), a titanium oxide (e.g., TiO₂), or a tin oxide (e.g., SnO₂).

The surface region 752 defines a thickness t₇ that is less than a thickness T₇ of the cover member 734. The thickness of the surface region 752 may depend upon the mechanism by which the structural color is created in a similar manner as previously discussed with respect to FIG. 5.

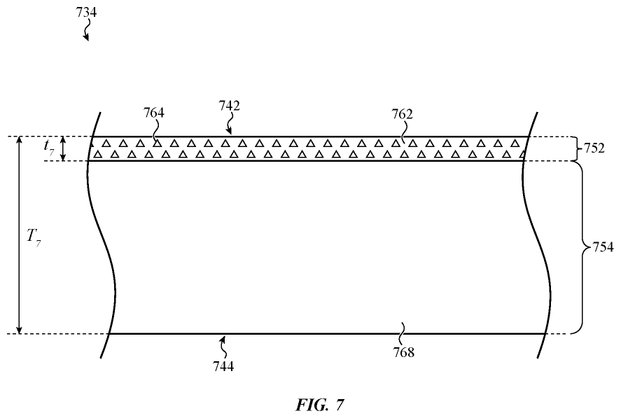

FIG. 8 shows another partial cross-section view of an enclosure component. The cover member 834 is a structurally colored enclosure component that includes a modified surface region 852 which extends along and defines an exterior surface 842 of the cover member. An underlying region 854, which is also referred to herein as a substrate region, defines an interior surface 844 of the cover member. The cover member 834 may be an example of the enclosure component 434 and the cross-section view of FIG. 8 may be an example of a cross-section along C-C in detail area 1-1 of FIG. 4.

As schematically illustrated in FIG. 8, the substrate region 854 includes crystals 865 and the surface region 852 is substantially free of the crystals 865. Therefore, the internal structure of the surface region 852 is modified from the internal structure of the substrate region 854 by the removal of the crystals 865 (vitrification). As shown in FIG. 8, the substrate region 854 includes a glass ceramic material that comprises the crystals 865 in a matrix of a first glass material 868. The surface region 852 includes a second glass material 862 and the surface region 852 is vitrified as compared to the substrate region 854. The average refractive index of the surface region 852 may be different than the average refractive index of the substrate region 854 due to the crystals 865 and in some cases the surface region 852 may have an index of refraction that is lower than that of the substrate region 854. The first glass material 868 and the second glass material 862 may differ in internal structure, chemical composition, or both. For example, the second glass material 868 may have a different composition than the first glass material 862 due to the formation of the crystals 865. In some examples, both the first glass-based material and the second glass-based materials are silicate glass materials.

The surface region 852 defines a thickness t₈ that is less than a thickness T₈ of the cover member 834. The surface region 852 may define a thin film having a thickness less than 5 micrometers or less than 1 micrometer as previously discussed with respect to FIG. 5.

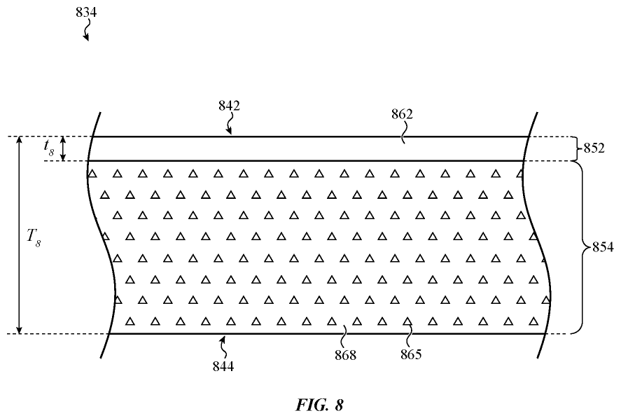

FIG. 9 shows another partial cross-section view of an enclosure component. The cover member 934 is a structurally colored enclosure component that includes a modified surface region 952 which extends along and defines an exterior surface 942 of the cover member. An underlying region 954, which is also referred to herein as a substrate region, defines an interior surface 944 of the cover member. The cover member 934 may be an example of the enclosure component 434 and the cross-section view of FIG. 9 may be an example of a cross-section along C-C in detail area 1-1 of FIG. 4.

As schematically illustrated in FIG. 9, the substrate region 954 includes a first set of crystals 965 and the surface region 952 includes a second set of crystals 964. Therefore, the internal structure of the surface region 952 is modified as compared to the internal structure of the substrate region 954 due to the difference(s) between the crystals 965 and 964. The concentration of the second set of crystals 964 is greater than the concentration of the first set of crystals 965. The crystals of the second set of crystals 964 may have a similar composition and/or shape as the crystals 965 or may differ in composition and/or shape.

As previously discussed with respect to FIG. 5, the size of the crystals 964 within the surface region 952 may depend upon the mechanism by which the structural color is created. In some examples, the average size of the crystals 964 is smaller than wavelengths of visible light within the surface region so that the internal structure of the surface region defines an effective medium for light traveling through the surface region. For example, the crystals 964 may have an average size that is greater than zero and less than 50 nm or less than 25 nm. In other examples, the size of the crystals 964 may be generally on the order of one or more wavelengths of visible light within the surface region. The size of the crystals 964 and 965 is enlarged for convenience of illustration, and the shape, the average volume fraction, and the distribution of the crystals shown in FIG. 9 is exemplary rather than limiting.

As shown in FIG. 9, the substrate region 954 includes a first glass ceramic material and the surface region 952 includes second glass ceramic material that is different from the first glass ceramic material. The average refractive index of the surface region 952 may be different than the average refractive index of the substrate region 954. As an example, the crystals 964 may be distributed in a matrix of the second glass material 962 and the crystals 965 may be distributed in a matrix of the first glass material 962. The first glass material 968 and the second glass material 962 may differ in internal structure, chemical composition, or both. In some examples, both the first glass material and the second glass materials are silicate glass materials.

The surface region 952 defines a thickness t₉ that is less than a thickness T₉ of the cover member 934. The thickness of the surface region 952 may depend upon the mechanism by which the structural color is created in a similar manner as previously discussed with respect to FIG. 5.

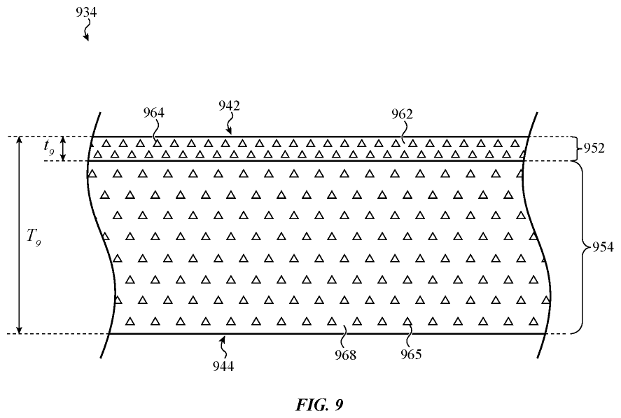

FIG. 10 shows another partial cross-section view of an enclosure component. The cover member 1034 is a structurally colored enclosure component that includes a modified surface region 1052 which extends along and defines an exterior surface 1042 of the cover member. An underlying region 1054, which is also referred to herein as a substrate region, defines an interior surface 1044 of the cover member. The cover member 1034 may be an example of the enclosure component 434 and the cross-section view of FIG. 10 may be an example of a cross-section along C-C in detail area 1-1 of FIG. 4.

As schematically illustrated in FIG. 10, the surface region 1052 has a phase separated structure that includes a first phase 1062 and a second phase 1064 and the substrate region 1054 lacks this phase separated structure. Therefore, the internal structure of the surface region 1052 is modified as compared to the internal structure of the substrate region 1054 by phase separation within the surface region 1052. As previously discussed with respect to FIG. 5, the size of the phases 1062 and 1064 within the surface region 1052 may depend upon the mechanism by which the structural color is created. In some examples, the average size of the phases 1062 and 1064 is smaller than wavelengths of visible light within the surface region so that the internal structure of the surface region defines an effective medium for light traveling through the surface region. For example, the phases 1062 and 1064 may have an average dimension that is greater than zero and less than 50 nm, from 25 nm to 150 nm, or from 30 nm to 100 nm. In other examples, the size of the phases 1062 and 1064 may be generally on the order of one or more wavelengths of visible light within the surface region. The size of the phases 1062 and 1064 is enlarged for convenience of illustration, and the shape, the average volume fraction, and the distribution of the phases 1062 and 1064 shown in FIG. 10 is exemplary rather than limiting.

In some cases, the substrate region 1054 may include or be formed of a glass 1068 that may separate into two or more phases upon heat treatment. The heat treatment may be localized at the glass surface. For example, the glass 1068 may be a borosilicate glass (alternately, a borosilicate glass material). The phases 1062 and 1064 may be two different glass phases (e.g., a borate-rich phase and a silica-rich phase). In some cases, the average refractive index of the surface region 1052 may be different than the average refractive index of the substrate region 1054. For example, the refractive index difference between the phase 1062 and the phase 1064 may be greater than 0.1. The first glass 1068 and the second glass-based materials 1062 and 1064 may differ in internal structure, chemical composition, or both.

The surface region 1052 defines a thickness t₁₀ that is less than a thickness T₁₀ of the cover member 1034. The thickness of the surface region 1052 may depend upon the mechanism by which the structural color is created in a similar manner as previously discussed with respect to FIG. 5. In some cases, a phase separated structure can be produced by spinodal decomposition, which can form a sub-micron scale interconnected structure. In other cases, a phase separated structure can be produced by nucleation and grown of discrete (e.g., spherical) phases embedded in a glassy matrix. A phase separated region that is concentrated at the surface may be produced by a heat treatment that is localized at the glass surface. In the example of FIG. 10, the phase separated region is concentrated at the surface but in other examples the phase separation can be present in the bulk of the enclosure component and produced by bulk heat treatment.

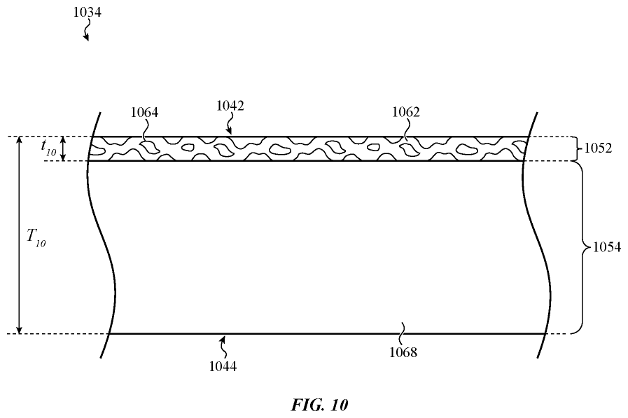

FIG. 11 shows another partial cross-section view of an enclosure component. The cover member 1134 is a structurally colored enclosure component in which the structural color is present on only a portion of the exterior surface of the cover member. The cover member 1134 may be an example of the rear cover member 134 and the cross-section view of FIG. 11 may be an example of a cross-section along A-A in FIG. 1B.

In the example of FIG. 11, the modified surface region 1152 extends along a portion of the exterior surface defined by a thicker portion of the cover member 1134. The substrate region 1154 extends below the modified surface region 1152 and defines an interior surface of the cover member in the thicker portion of the cover member. The substrate region 1154 defines both interior and exterior surfaces of the cover member in the thinner portion of the cover member. In the example of FIG. 11, the surface region 1152 defines a thickness t₁₁ that is less than a thickness T₁₁ of the thinner region of the cover member 1134. The thickness of the surface region 1152 may depend upon the mechanism by which the structural color is created in a similar manner as previously discussed with respect to FIG. 5. The difference between the thinner and the thicker portions of the cover member is indicated as ΔT₁₁ in FIG. 11.

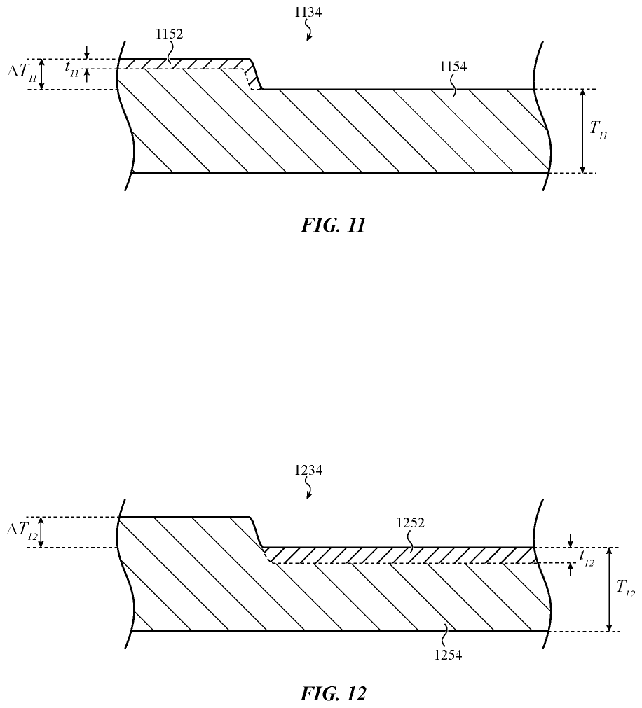

FIG. 12 shows another partial cross-section view of an enclosure component. The cover member 1234 is a structurally colored enclosure component in which the structural color is present on only a portion of the exterior surface of the cover member. The cover member 1234 may be an example of the rear cover member 134 and the cross-section view of FIG. 12 may be an example of a cross-section along A-A in FIG. 1B.

In the example of FIG. 12, the modified surface region 1252 extends along a portion of the exterior surface defined by a thinner portion of the cover member 1234. In the example of FIG. 12, the modified surface region 1252 extends along a portion of the exterior surface defined by a thinner portion of the cover member 1234. The substrate region 1254 extends below the modified surface region 1252 and defines an interior surface of the cover member in the thinner portion of the cover member. The substrate region 1254 defines both interior and exterior surfaces of the cover member in the thicker portion of the cover member. In the example of FIG. 12, the surface region 1252 defines a thickness t₁₂ that is less than a thickness Tie of the thinner region of the cover member 1234. The thickness of the surface region 1252 may depend upon the mechanism by which the structural color is created in a similar manner as previously discussed with respect to FIG. 5. The difference between the thinner and the thicker portions of the cover member is indicated as ΔT₁₂ in FIG. 12.

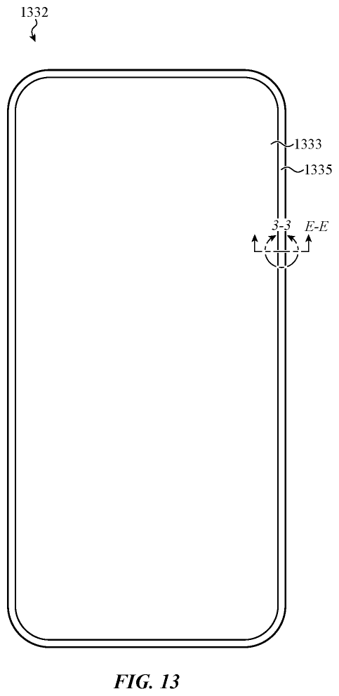

FIG. 13 shows another enclosure component of an electronic device. The cover member 1332 is a structurally colored enclosure component in which the structural color may be present on only a portion of the exterior surface of the cover member. The enclosure component 1332 of FIG. 13 may be an example of the front cover member 132 of FIG. 1A.

In some embodiments, the cover member 1332 includes a modified surface region that extends over less than an entirety of the exterior surface of the cover member 1332. In some cases, the modified surface region may extend along an exterior surface of the peripheral portion 1335 but may not extend along the portion 1333 that is interior to the peripheral portion. The modified surface region of the peripheral portion 1335 may, solely or in combination with an underlying region of the cover member, produce a structural color in a similar fashion as previously discussed at least with respect to FIGS. 4 and 5. The portion 1333 may be positioned over a display of the electronic device. In some cases, such as in the example of FIG. 13, the portion 1333 is a central portion of the enclosure component.

The modified surface region of the peripheral portion 1335 may have a different internal structure than an underlying portion of the peripheral portion, as previously described with respect to at least FIGS. 4-12. The modified surface region of the peripheral portion may also have a different internal structure than the portion 1333 of the cover member 1332 that is interior to the peripheral portion 1335. The internal structure of the portion 1333 may be suitable for use over a display. For example, the internal structure of the portion 1333 may be configured to produce a suitable level of light transmission and clarity with minimum haze.

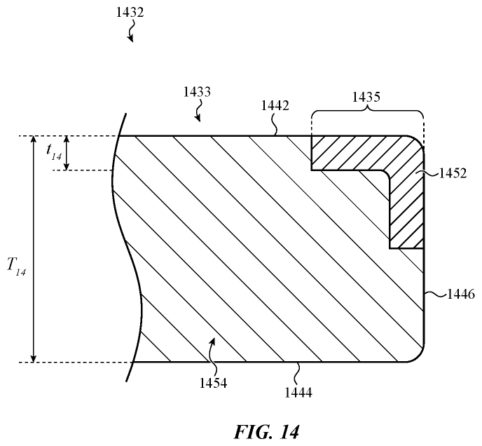

FIG. 14 shows an example partial cross-section view of an enclosure component. The cover member 1432 is a structurally colored enclosure component in which the structural color is present only in a peripheral portion 1435 of the exterior surface of the cover member. The cover member 1432 may be an example of the cover member 1332 and the cross-section view of FIG. 14 may be an example of a cross-section along E-E in detail area 3-3 of FIG. 13.

In the example of FIG. 14, the modified surface region 1452 extends over a portion of a front surface 1442 and a portion of a side surface 1446 in the peripheral portion 1435 of the cover member. The substrate region 1454 is positioned below the modified surface region 1452 in the peripheral region 1435 but defines a portion of both the exterior surface 1442 and the interior surface 1444 in the portion 1433.

As previously discussed with respect to FIG. 14, the modified surface region 1452 of the peripheral portion 1435 may have a different internal structure than an underlying portion of the substrate region 1454, examples of which were previously described with respect to at least FIGS. 4-12. The modified surface region of the peripheral portion 1435 may also have a different internal structure than the substrate region 1454 in the portion 1433 of the cover member 1432. The internal structure of the portion 1433 of the cover member 1432 may be suitable for use over a display.

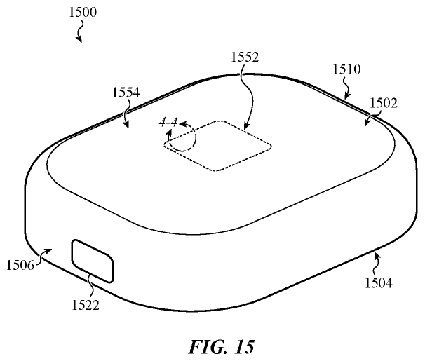

FIG. 15 shows another example electronic device. The electronic device 1500 of FIG. 15 has a structurally colored enclosure in which the structural color is present only in portion of the enclosure. In contrast to the electronic device of FIGS. 1A and 1B, the electronic device 1500 may not include a display.

In the example of FIG. 15, the modified surface region 1552 extends along a portion of the front surface 1502 of the housing 1510. However, the modified surface region 1152 does not extend along the side surface 1506 or the rear surface 1504 of the housing 1510. The modified surface region 1552 may have a different internal structure than a substrate portion 1554 of the housing, examples of which were previously described with respect to at least FIGS. 4 through 12 and that description is not repeated here. For example, a cross-section through the detail region 4-4 may be similar to any one of the cross-sections shown in FIGS. 5-12.

In the example of FIG. 15, the housing 1510 defines an opening 1522. In some cases, the opening 1522 may provide a port for charging the electronic device. In additional examples, the housing may define one or more openings for internal components that receive input and/or produce output. In aspects of the disclosure, the electronic device 1500 includes one or more electronic components. In some cases, the electronic device may include one or more of a processor, electronic circuitry (e.g., control circuitry), a sensor, memory, and a battery. More generally, the electronic components may be any of those discussed with respect to FIG. 16 and that description is not repeated here. The housing 1500 may define an interior volume configured to receive one or more of the electronic components, such as a battery and electronic circuitry.

FIG. 16 shows a block diagram of an example electronic device that includes a structurally colored enclosure component as described herein. The schematic representation depicted in FIG. 16 may correspond to components of the devices depicted in FIGS. 1A to 1B and 15 as described above. However, FIG. 16 may also more generally represent other types of electronic devices including a component comprising a composite material as described herein.

In embodiments, an electronic device 1600 may include sensors 1620 to provide information regarding configuration and/or orientation of the electronic device in order to control the output of the display. For example, a portion of the display 1608 may be turned off, disabled, or put in a low energy state when all or part of the viewable area of the display 1608 is blocked or substantially obscured. As another example, the display 1608 may be adapted to rotate the display of graphical output based on changes in orientation of the device 1600 (e.g., 90 degrees or 180 degrees) in response to the device 1600 being rotated.

The electronic device 1600 also includes a processor 1606 operably connected with a computer-readable memory 1602. The processor 1606 may be operatively connected to the memory 1602 component via an electronic bus or bridge. The processor 1606 may be implemented as one or more computer processors or microcontrollers configured to perform operations in response to computer-readable instructions. The processor 1606 may include a central processing unit (CPU) of the device 1600. Additionally, and/or alternatively, the processor 1606 may include other electronic circuitry within the device 1600 including application specific integrated chips (ASIC) and other microcontroller devices. The processor 1606 may be configured to perform functionality described in the examples above.

The memory 1602 may include a variety of types of non-transitory computer-readable storage media, including, for example, read access memory (RAM), read-only memory (ROM), erasable programmable memory (e.g., EPROM and EEPROM), or flash memory. The memory 1602 is configured to store computer-readable instructions, sensor values, and other persistent software elements.

The electronic device 1600 may include control circuitry 1610. The control circuitry 1610 may be implemented in a single control unit and not necessarily as distinct electrical circuit elements. As used herein, “control unit” will be used synonymously with “control circuitry.” The control circuitry 1610 may receive signals from the processor 1606 or from other elements of the electronic device 1600.

As shown in FIG. 16, the electronic device 1600 includes a battery 1614 that is configured to provide electrical power to the components of the electronic device 1600. The battery 1614 may include one or more power storage cells that are linked together to provide an internal supply of electrical power. The battery 1614 may be operatively coupled to power management circuitry that is configured to provide appropriate voltage and power levels for individual components or groups of components within the electronic device 1600. The battery 1614, via power management circuitry, may be configured to receive power from an external source, such as an alternating current power outlet. The battery 1614 may store received power so that the electronic device 1600 may operate without connection to an external power source for an extended period of time, which may range from several hours to several days.

In some embodiments, the electronic device 1600 includes one or more input devices 1618. The input device 1618 is a device that is configured to receive input from a user or the environment. The input device 1618 may include, for example, a push button, a touch-activated button, a capacitive touch sensor, a touch screen (e.g., a touch-sensitive display or a force-sensitive display), a capacitive touch button, dial, crown, or the like. In some embodiments, the input device 1618 may provide a dedicated or primary function, including, for example, a power button, volume buttons, home buttons, scroll wheels, and camera buttons.

The device 1600 may also include one or more sensors or sensor modules 1620, such as a force sensor, a capacitive sensor, an accelerometer, a barometer, a gyroscope, a proximity sensor, a light sensor, or the like. In some cases, the device 1600 includes a sensor array (also referred to as a sensing array) which includes multiple sensors 1620. For example, a sensor array associated with a protruding feature of a cover member may include an ambient light sensor, a Lidar sensor, and a microphone. As previously discussed with respect to FIGS. 1B and 2, one or more camera modules may also be associated with the protruding feature. The sensors 1620 may be operably coupled to processing circuitry. In some embodiments, the sensors 1620 may detect deformation and/or changes in configuration of the electronic device and be operably coupled to processing circuitry that controls the display based on the sensor signals. In some implementations, output from the sensors 1620 is used to reconfigure the display output to correspond to an orientation or folded/unfolded configuration or state of the device. Example sensors 1620 for this purpose include accelerometers, gyroscopes, magnetometers, and other similar types of position/orientation sensing devices. In addition, the sensors 1620 may include a microphone, an acoustic sensor, a light sensor (including ambient light, infrared (IR) light, ultraviolet (UV) light), an optical facial recognition sensor, a depth measuring sensor (e.g., a time of flight sensor), a health monitoring sensor (e.g., an electrocardiogram (erg) sensor, a heart rate sensor, a photoplethysmogram (ppg) sensor, a pulse oximeter, a biometric sensor (e.g., a fingerprint sensor), or other types of sensing device.

In some embodiments, the electronic device 1600 includes one or more output devices 1604 configured to provide output to a user. The output device 1604 may include a display 1608 that renders visual information generated by the processor 1606. The output device 1604 may also include one or more speakers to provide audio output. The output device 1604 may also include one or more haptic devices that are configured to produce a haptic or tactile output along an exterior surface of the device 1600.

The display 1608 may include a liquid-crystal display (LCD), a light-emitting diode (LED) display, an LED-backlit LCD display, an organic light-emitting diode (OLED) display, an active layer organic light-emitting diode (AMOLED) display, an organic electroluminescent (EL) display, an electrophoretic ink display, or the like. If the display 1608 is a liquid-crystal display or an electrophoretic ink display, the display 1608 may also include a backlight component that can be controlled to provide variable levels of display brightness. If the display 1608 is an organic light-emitting diode or an organic electroluminescent-type display, the brightness of the display 1608 may be controlled by modifying the electrical signals that are provided to display elements. In addition, information regarding configuration and/or orientation of the electronic device may be used to control the output of the display as described with respect to input devices 1618. In some cases, the display is integrated with a touch and/or force sensor in order to detect touches and/or forces applied along an exterior surface of the device 1600.

The electronic device 1600 may also include a communication port 1612 that is configured to transmit and/or receive signals or electrical communication from an external or separate device. The communication port 1612 may be configured to couple to an external device via a cable, adaptor, or other type of electrical connector. In some embodiments, the communication port 1612 may be used to couple the electronic device 1600 to a host computer.

The electronic device 1600 may also include at least one accessory 1616, such as a camera, a flash for the camera, or other such device. The camera may be part of a camera array or sensing array that may be connected to other parts of the electronic device 1600 such as the control circuitry 1610.

The following discussion applies to the electronic devices described herein to the extent that these devices may be used to obtain personally identifiable information data. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

As referred to herein, a composition that is substantially free of one or more elements or compounds may contain only an incidental amount of the element or compound. In some examples, the composition may include less than 0.1 at % of the element or compound.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A portable electronic device comprising:
a display; and
an enclosure including a cover assembly comprising a unitary cover member comprising:
a substrate region formed from a first glass-based material and having a first refractive index; and
a surface region adjacent to the substrate region and defining an exterior surface of the unitary cover member, the surface region comprising:
a matrix formed from a second glass-based material and having a second refractive index; and
an array of features within the matrix and having a third refractive index that is different than the first refractive index, the substrate region and the surface region configured to produce a reflected color that varies as a function of viewing angle.

2. The portable electronic device of claim 1, wherein:
the array of features comprises an array of pores; and
an average refractive index of the surface region is less than the first refractive index.

3. The portable electronic device of claim 2, wherein the pores of the array of pores have an average size ranging from 1 nm to 20 nm.

4. The portable electronic device of claim 1, wherein the array of features comprises an array of ceramic crystals.

5. The portable electronic device of claim 1, further comprising a rear-facing camera assembly, wherein:
the unitary cover member is positioned over the rear-facing camera assembly; and
the cover assembly further comprises a polymer-based coating disposed over an interior surface of the unitary cover member.

6. The portable electronic device of claim 5, wherein:
a first portion of the unitary cover member positioned over the rear-facing camera assembly is thicker than a second portion of the unitary cover member surrounding the first portion; and
the surface region is located in the second portion of the unitary cover member.

7. The portable electronic device of claim 1, wherein:
the unitary cover member is a front cover member;
the front cover member defines a window portion positioned over the display; and
the surface region is located in a peripheral portion of the front cover member that surrounds the window portion.

8. An electronic device comprising:
an enclosure comprising:
a housing assembly; and
a rear cover assembly coupled to the housing assembly, defining a rear surface of the electronic device, and including:
a cover member comprising:
a first layer defined by a first glass-based material having a first index of refraction; and
a second layer defining an exterior surface of the cover member, defined by a second glass-based material, and having a second index of refraction that is less than the first index of refraction, the surface and the substrate layers configured to produce an iridescent optical effect along the exterior surface of the electronic device; and
a polymer-based coating disposed over an interior surface of the cover member, the polymer-based coating configured to reflect at least a portion of light transmitted through the cover member; and
an internal electronic component positioned within the enclosure and below the first layer and the second layer of the cover member.

9. The electronic device of claim 8, wherein the internal electronic component is a radio-frequency antenna assembly positioned under the first layer and the second layer of the cover member.

10. The electronic device of claim 9, wherein the second layer has a thickness less than 1 micrometer.

11. The electronic device of claim 9, wherein:
the second layer comprises pores within the second glass-based material; and
the first layer is substantially non-porous.

12. The electronic device of claim 11, wherein the pores have an average size that is less than 50 nm.

13. The electronic device of claim 8, wherein:
the first glass-based material is a first silicate glass material; and
the second glass-based material is a second silicate glass material derived from the first silicate glass material.

14. The electronic device of claim 8, wherein:
the first layer comprises a first set of metallic nanoparticles;
the second layer comprises a second set of metallic nanoparticles; and
each of the first set and the second set of metallic nanoparticles contribute to a color of the rear cover assembly.

15. A portable electronic device comprising:
a display;
a camera assembly; and
an enclosure at least partially surrounding the display, the enclosure comprising:
a housing assembly defining a set of side surfaces of the portable electronic device;
a front cover assembly positioned over the display and defining a front surface of the portable electronic device; and
a rear cover assembly positioned over the camera assembly and defining a rear surface of the portable electronic device, the rear cover assembly including a cover member defining:
a substrate region defining an interior surface of the cover member, comprising a first glass-based material, and having a first internal structure; and
a surface region defining an exterior surface of the cover member, comprising a second glass-based material, and having a second internal structure different from the first internal structure and configured to produce iridescence at the exterior surface of the cover member.

16. The portable electronic device of claim 15, further comprising a wireless charging coil, wherein:
the surface region and the substrate region are positioned over the wireless charging coil; and
the wireless charging coil is configured to receive wireless power from an external power supply through the cover member of the rear cover assembly.

17. The portable electronic device of claim 15, wherein:
the second internal structure is defined at least in part by ceramic particles in a matrix of the second glass-based material; and
the ceramic particles have an index of refraction that is different from an index of refraction of the second glass-based material.

18. The portable electronic device of claim 15, wherein:
the second internal structure is defined at least in part by the second glass-based material and a third glass-based material; and
an index of refraction of the second glass-based material is different from an index of refraction of the third glass-based material.

19. The portable electronic device of claim 18, wherein the first glass-based material is a borosilicate glass material.

20. The portable electronic device of claim 15, wherein the second internal structure defines a photonic crystal.
